(19) United States
(12) Patent Application Publication
(10) Pub. No.: US 2006/0264014 A1
(43) Pub. Date: Nov. 23, 2006

(54) Structures, materials and methods for fabrication of nanostructures

(76) Inventor: Robert W. Bower, Haiku, HI (US)

Correspondence Address: JOHN P. O'BANION;O'BANION & RITCHEY LLP, 400 CAPITOL MALL SUITE 1550, SACRAMENTO, CA, 95814, US

(21) Appl. No.: 11/335,162

(22) Filed: Jan. 18, 2006

Related U.S. Application Data
(63) Continuation-in-part of application No. 10/763,578, filed on Jan. 21, 2004.
(60) Provisional application No. 60/645,172, filed on Jan. 19, 2005.

(51) Int. Cl. H01L 27/12; H01L 21/30; H01L 21/425

(52) U.S. Cl. 438/514; 438/455; 257/347

(57) ABSTRACT

A material having a top portion (active layer) of a thickness and other characteristics optimized for formation of a desired nanostructure, followed by an insulator layer (intermediate or boundary layer) chosen for its electrical insulation and etch resistance from a substrate material formed adjacent to it such that after subsequent processing the substrate may be removed by polishing and etching to leave the nanostructure processed top layer as a thin layer bonded to a 3-d stack or other structure as a thin layer. Thus, the substrate layer has been optimized to have a very high etch rate and to have a large difference in its etch rate and that of the intermediate insulator layer so that it can be selectively etched.

### CROSS-REFERENCE TO RELATED APPLICATIONS

This application claims priority to U.S. provisional application Ser. No. 60/645,172 filed on Jan. 19, 2005, incorporated herein by reference in its entirety. This application is also a continuation-in-part of U.S. patent application Ser. No. 10/763,578 filed on Jan. 21, 2004, incorporated herein by reference in its entirety.

### STATEMENT REGARDING FEDERALLY SPONSORED RESEARCH OR DEVELOPMENT

Not Applicable

### INCORPORATION-BY-REFERENCE OF MATERIAL SUBMITTED ON A COMPACT DISC

Not Applicable

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. § 1.14.

### BACKGROUND OF THE INVENTION

1. Field of the Invention

This invention pertains generally to expunging material layers within a solid, and more particularly to methods for resolving forward skew and enhancing the transfer of an expunged layer or layer to a target material.

2. Description of Related Art

A basic way to form 3-dimensional nanostructures is to create in a chip or wafer a layer on nanostructure on a substrate, then attach the formed nanostructure onto an existing 3-dimensional handle structure and then thin the added layer to complete the structure. This is illustrated in FIG. 1.

This is the basic method that is used in prior art 3-dimensional stacked nanoarrays. The problems with this basic method are described below.

The prior art methods of thinning do not produce layers that are nearly as thin as possible or desired for the following reasons:

1. The back surface of the material that is being thinned will generally not be flat and parallel to the front surface where the nanostructures are formed. Thus, as the grind and etch process proceeds the process must be stopped at a substantial distance from the front surface since the stopping plane will not match the top surface plane. The thinned material has been found to be limited to a value of greater than 10-15 um in a manufacturing production environment. See FIG. 2.

2. There is not a well defined end point to stop the grind and etch back procedure. This generally makes it difficult to control such an open-ended process in a manufacturing production environment. This limitation also causes a processes where the thinned material is limited to a value of the order of 5 μm. See FIG. 3.

The result of these two problems is that the overall thinning process must be limited to a thickness of the approximately the rms sum of these two limiting problems or ˜15-20 μm.

The depth of the active layer of a current high density nanostructure is a fraction of a micrometer and will become thinner with future devices. Thus, the thickness of layers produced by the prior art bond and grind and etch back method of making 3-dimensional stacks is at best about 20 times thicker than required. This means that the density of such stacks is at least 20 times less than would be theoretically possible in an ideal stacked layer. Furthermore, the vertical interconnection vias that connect signals between the layers of the 3-dimensional stacks are 20 times or more as long as theoretically required by device spacing considerations. Such super vias as they are sometimes called are difficult to manufacture and limited to large diameters unsuitable to the feature size required by vertical interconnections in current and future nanostructures Thus, these current methods of forming 3-dimensional stacked nanostructures substantially limit the density and manufacturability of 3-dimensional stacked arrays made with them.

### BRIEF SUMMARY OF THE INVENTION

In my prior work, described in detail in U.S. Published Patent Application No. 2004-0229443 A1, incorporated herein by reference in its entirety, I describe a material which I refer to as “Material-X” as well as methods for fabricating Material-X. In the description that follows, I describe an alternative material which I refer to as “Material-Y”.

Referring to FIG. 4, the present invention, which I refer to as “Material-Y”, comprises a top portion (active layer) of a thickness and other characteristics optimized for formation of a desired nanostructure, followed by an insulator layer (intermediate or boundary layer) chosen for its electrical insulation and etch resistance from a substrate material formed adjacent to it such that after subsequent processing the substrate may be removed by polishing and etching to leave the nanostructure processed top layer as a thin layer bonded to a 3-d stack or other structure as a thin layer. Thus, the substrate layer has been optimized to have a very high etch rate and to have a large difference in its etch rate and that of the intermediate insulator layer so that it can be selectively etched. Certain structures that would qualify as Material-Y would be a subset of material generically called SOI.

An aspect of the invention is a nanostructure comprising an active layer and at least one active device embedded in the active layer wherein the active layer has a thickness not thicker than the thickest active device that includes the depth needed for the active device to operate properly.

Another aspect of the invention is a nanostructure comprising an active layer and at least one active device embedded in the active layer wherein the active layer has a thickness not greater than 20 times the thickness required for the active device to operate properly.

A further aspect of the invention is a three-dimensional nanostructure comprising a plurality of nanodevices, each said nanodevice having an active layer and at least one active device embedded in the active layer, wherein the active layer has a thickness approximately the thickness of the active device in the active layer, and wherein vertical interconnections between said nanodevices have a length approximately the thickness of the active layer.

A still further aspect of the invention is a three-dimensional nanostructure comprising a plurality of nanodevices, each said nanodevice having an active layer and at least one active device embedded in the active layer, wherein the active layer has a thickness not thicker than 20 times the thickness needed for the active device in the active layer to perform properly, and wherein vertical interconnections between said nanodevices have a length not more than 20 times the depth needed for the active device in the active layer to perform properly.

Another aspect of the invention is a material for use in fabricating a nanodevice, comprising an active layer, a substrate layer, and a boundary layer intermediate said active layer and said substrate layer.

According to another aspect of the invention, the active layer has a top surface having a contour, and the boundary layer has a contour that matches the contour of said top surface of said active layer.

According to another aspect of the invention the boundary layer is configured to allow thinning of said active layer to a thickness required by one or more device structures on said active layer. According to a further aspect of the invention, the boundary layer comprises a sacrificial layer. According to another aspect of the invention, the boundary layer comprises an etch stop layer. In one embodiment, the boundary layer comprises SiO₂. According to another aspect of the invention, the boundary layer isolates said active layer from said substrate layer. In one embodiment, the boundary layer has a high segregation coefficient with respect to said substrate layer with an enchant used to remove the substrate layer, and the boundary layer is configured for etch removal without etching or otherwise damaging the active layer during its removal.

According to another aspect of the invention, the substrate layer comprises a material that allows rapid grinding and selective etching of the substrate from the boundary layer.

According to a further aspect of the invention, the active layer comprises a material optimized to characteristics of a device structure to be formed in said active layer. In various embodiments, the active layer comprises a material selected from the group of materials consisting essentially of silicon or strained silicon, Ge III-V, II-VI semiconductors or any other material that is suitable for the desired material. According to another aspect of the invention, the active layer has a thickness selected to facilitate fabrication of a device structure in said active layer. According to another aspect of the invention, the active layer has a thickness ranging from a fraction of a micrometer to several micrometers.

In according with a further aspect of the invention, the substrate layer comprises a sacrificial layer, the boundary layer comprises a sacrificial layer, and removal of said substrate layer and said boundary layer produces an active layer having a thickness equivalent to thickness of a device formed in said active layer. In various embodiments, the substrate layer comprises silicon or other material compatible with standard silicon semiconductor processing environments. In one embodiment, the substrate layer has a thickness, shape and size of a standard wafer. According to an aspect of the invention, the substrate layer comprises a sacrificial layer.

In one embodiment of the invention, a method of fabricating a nanodevice, comprises forming a material comprising an active layer, a substrate layer, and a boundary layer intermediate said active layer and said substrate layer; processing the active layer with a device; planarizing the active layer; bonding the active layer to a handle or 3-dimensional stack; thinning a portion of said substrate layer using a combination of grinding and etching; thinning the remainder of said substrate layer with an etch that stops at or within the boundary layer; and thinning said boundary layer to a locating at or near said active layer. In one embodiment, required via feed-through conductors to electrically connect the processed active layer to another structure are formed after thinning. In one embodiment, the feed-through conductors are preformed in said active layer. In another embodiment, the material is coated said material with a protective layer prior to thinning.

In one embodiment, the protective layer comprises silicon nitride or other such materials. In one embodiment, grinding of the substrate removes all but 25 μm to 50 μm of the substrate. In one embodiment, etching of the substrate layer removes said remaining substrate layer and stops on or within the boundary layer. In a further embodiment, the boundary layer comprises SiO₂ and is etched with an etchant selected from the group consisting essentially of SF₆, XeF₂, KOH, and EDP.

According to another embodiment of the invention, a multilayered material for fabrication of a nanodevice comprises (a) a device layer; (b) an insulator layer adjacent to said device layer; and (c) a substrate layer adjacent to the insulator layer; (d) wherein the device layer has a thickness and other characteristics optimized for processing of a desired nanostructure on the device layer; (e) wherein the insulator layer has electrical insulation characteristics and etch resistance from the substrate layer such that, after subsequent processing, the substrate may be removed by polishing and etching to leave a nanostructure processed device layer as a thin layer bonded to a 3-d stack or other structure as a thin layer; and (f) wherein the substrate layer has been optimized to have a very high etch rate and to have a large difference between its etch rate and the etch rate of the insulator layer so that it can be selectively etched.

According to another embodiment of the invention, a method for fabricating a multilayered material for fabrication of a nanodevice, comprises (a) forming a device layer; (b) forming an insulator layer adjacent to said device layer; and (c) forming a substrate layer adjacent to the insulator layer; (d) wherein the device layer has a thickness and other characteristics optimized for processing of a desired nanostructure on the device layer; (e) wherein the insulator layer has electrical insulation characteristics and etch resistance from the substrate layer such that, after subsequent processing, the substrate may be removed by polishing and etching to leave a nanostructure processed device layer as a thin layer bonded to a 3-d stack or other structure as a thin layer; and (f) wherein the substrate layer has been optimized to have a very high etch rate and to have a large difference between its etch rate and the etch rate of the insulator layer so that it can be selectively etched.

In a further embodiment of the invention, a method for forming a processed nanostructure, comprises (a) forming a device layer; (b) forming an insulator layer adjacent to said device layer; and (c) forming a substrate layer adjacent to the insulator layer; (d) wherein the device layer has a thickness and other characteristics optimized for processing of a desired nanostructure on the device layer; (e) wherein the insulator layer has electrical insulation characteristics and etch resistance from the substrate layer such that, after subsequent processing, the substrate may be removed by polishing and etching to leave a nanostructure processed device layer as a thin layer bonded to a 3-d stack or other structure as a thin layer; (f) wherein the substrate layer has been optimized to have a very high etch rate and to have a large difference between its etch rate and the etch rate of the insulator layer so that it can be selectively etched; (g) wherein the thickness, size and other characteristics of the multilayer structure comprising the device layer, insulator layer and substrate layer are selected to meet the requirements of an integrated circuit (IC) or other fabrication line; (h) processing the device layer to produce a desired nanostructure; (i) align bonding the multilayer structure to a 3-d stack or other desired structure; (j) thinning the substrate layer to only the insulator layer and the nanostructure processed device layer attached to the 3-d stack or other desired structure; (k) selectively etching the insulator layer to leave only the thin nanostructure processed device layer attached to the 3-d stack or other structure.

In another embodiment, Material-Y is used to make 3-d structures as follows. Material-Y is made in wafer form to a thickness and size and other characteristics to match that used in the customer's integrated circuit (IC) or other fabrication line.

2. Material-Y is processed by the manufacturer to produce the customer's desired nanostructure.

3. Material-Y is then aligned bonded to a 3-d stack or other desired structure.

4. The substrate of Material-Y is then thinned back leaving only part or all of the intermediate insulator layer and nanostructure processed attached to the 3-d stack or other desired structure.

5. The intermediate insulator layer would then be selectively etched as desired leaving only the thin nanostructure processed layer attached to the 3-d stack or other structure.

6. Required via feed-through conductors would then be made to electrically connect this added layer to the entire structure. Since this layer of processed nanostructure may be ˜1 μm in thickness these interconnecting electrical vias are easily formed in a manner well known in the semiconductor industry.

7. Alternatively, the required via feed-through conductors could of course be made as part of the nanolayer before the bonding and grind and etch steps.

Further aspects and embodiments of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings which are for illustrative purposes only:

FIG. 1 illustrates a basic way to form 3-dimensional nanostructures is to create in a chip or wafer a layer on nanostructure on a substrate, then attach the formed nanostructure onto an existing 3-dimensional handle structure and then thin the added layer to complete the structure.

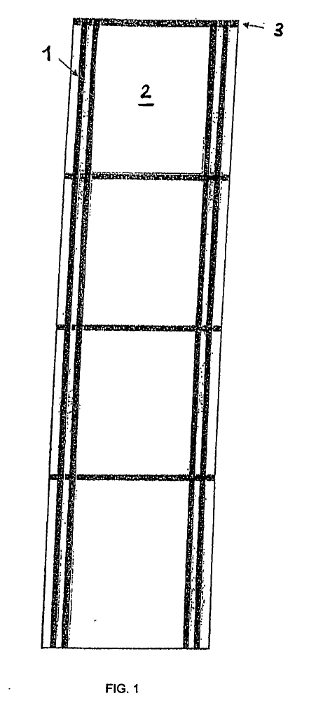

FIG. 2 illustrates that the back surface of the material that is being thinned according to the process of FIG. 1 will generally not be flat and parallel to the front surface where the nanostructures are formed.

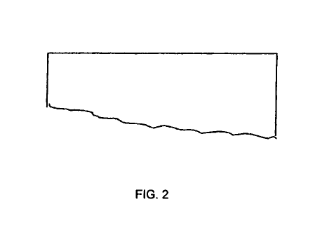

FIG. 3 illustrates that there is not a well defined end point to stop the grind and etch back procedure in the process of FIG. 1.

FIG. 4 illustrates “Material-Y” of the present invention.

FIG. 5 illustrates the ideal 3-dimensional thinned stack produced with a boundary layer process produced with either Material-X or Material-Y.

FIG. 6 compares a conventional and intermediate boundary layer 3-dimensional nanostructure stacks that would result from the either such stacks formed using the methods and structures described in U.S. Published Patent Application No. 2004-0229443 A1 with regard to Material-X or in the description herein with regard to Material-Y.

### DETAILED DESCRIPTION OF THE INVENTION

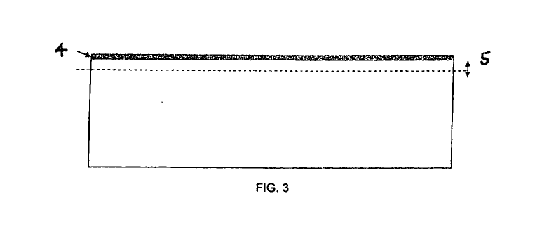

A substantial improvement over the prior art can be made by providing a boundary layer between the active material used to make the nanostructure material and the back substrate that follows the exact contour of the top surface where the nanostructure layers are formed. With such an intermediate boundary layer, the active layer can be thinned to near the theoretical minimum thickness required by device structures themselves. The selectivity of removal of a layer to such a boundary layer will have a direct effect on the degree that a layer of material can be thinned. This is illustrated in FIG. 3 of an article in the MRS Bulletin, December 1998 pgs 30-34 entitled Wafer-Bonding and Thinning Technologies by Desmond-Colinge and Goesele, incorporated herein by reference in its entirety. From this analysis it is recognized that a waviness and nonplanarity of the removed layer may be reduced by the factor of the selectivity, S, of the removal process. For example, with a removal selectivity of 100 a waviness and nonplanarity of 15 μm will be reduced to ˜0.15 μm. Thus, using such a boundary layer could improve the prior art process to one that creates layers that are a fraction of a micron (˜0.15 μm). When a sacrificial layer such as described for the intermediate boundary layer for Material-X or Material-Y is used as the etch stop, then the precision of the device can be further improved, since this sacrificial layer may be removed leaving only the active layer of either of these structures. After etching into or to the Intermediate boundary layer, there may be a subsequent etch to remove what remain of this layer. However, several very selective etches are known in the prior art that will selectively remove the remainder of the intermediate boundary layer, with minimal removal of the active layer. For example with an intermediate boundary layer of SiO₂ a vapor or wet etch of this layer in HF would leave the active layer virtually untouched. Thus, this process has an affective selectivity that is nearly infinite.

The Material-X structure and method described in detail in U.S. Published Patent Application No. 2004-0229443 A1, incorporated herein by reference in its entirety, provides such a boundary layer and is capable of creating 3-dimensional nanostructure stacks that are submicron and near ideal. Each and every publication, patent and patent application referenced in U.S. Published Patent Application No. 2004-0229443 A1, is also incorporated herein by reference in its entirety.

This invention, which is an improvement over Material X and the prior art, comprises structures and methods of producing a new Material-Y that also provides such a boundary layer and is capable of creating 3-dimensional nanostructure stacks that are submicron and near ideal. The structures and methods of producing Material-Y are substantially different than that found in Material-X or other prior art.

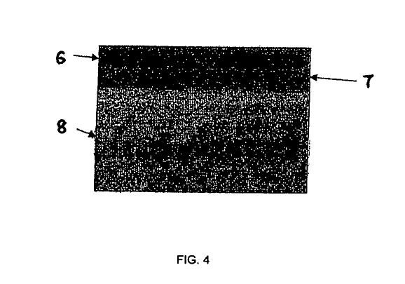

FIG. 4 illustrates the features of Material-Y. The top layer of Material-Y is precisely the same as that used in Material-X. Its material characteristics are chosen to optimize the characteristics of the nanostructure layer formed in it and its thickness is chosen to precisely that needed for the nanostructure layer. Within the scope of what can be achieved with this invention are active layers that range from those just thick enough to provide for the depth of the deepest structure in a given nanostructure to operate properly to active layers that are orders of magnitude greater than necessary for proper operation of the nanostructures contained in the layer. The greatest advantage of this invention over the conventional prior art for making 3-dimensional nanostructure stacks where the active layers are near the minimum thickness possible as described above. However, there is a range of greater thicknesses than this minimum where there is still merit in using the methods and devices of the present invention. In fact there is still merit in using the present invention to make active layers that range from the minimum to layers that are at least 20 times thicker than this minimum. Within this range this invention provides methods and structures that provide a real and measurable advantage over the conventional prior art methods currently used to form 3-dimensional stacks. Similarly, there is a range of vertical interconnect that also range from the shortest allowed by the present invention to a range that is much longer. These vertical interconnects will have a length approximately equal to the range of depth of the active layers just described.

The intermediate boundary layer is chosen to isolate the active layer from the rest of the structure. In Material-X, the boundary layer was chosen to allow the hydrogenation (transposed split) process to be accomplished without chemically or thermally affecting the active layer and other layers of the 3-dimensional stack. This was accomplished in the Material-X case by choosing the insulator from an insulator material that would chemically isolate the active layer from the hydrogen and thermally insulate the active layer and the 3-dimensional stack from the heat used in the hydrogenation process as well as to electrically isolate the active layer.

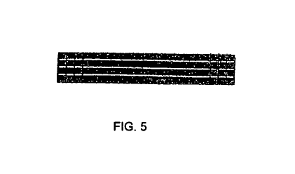

Material-Y is thinned by grinding and etching the substrate back to and stopping at the boundary layer. In the case of Material-Y this boundary layer is optimized to isolate the active layer and to provide a large segregation coefficient during the etching process of the bottom substrate layer. Thus, the material characteristics of the boundary layer must be chosen to have a very high segregation coefficient with respect to the back substrate material with the enchant used and it must be possible to etch the remaining boundary layer without etching or otherwise damaging the active layer during its removal. Thus, the boundary layer for Material-Y is quite different than Material-X. The bottom substrate layer of Material-Y is also significantly different than that of Material-X. In the case of Material-X, the bottom substrate is chosen to maximize the diffusion of hydrogen through the layer and it contains a hydrogen trapping layer to capture the hydrogen for the cut process of the transposed split. On the other hand, the bottom substrate layer of Material-Y is composed of a material that allows rapid grinding and selective etching of the substrate from the boundary layer. FIG. 5 illustrates the ideal 3-dimensional thinned stack produced with a boundary layer process produced with either Material-X or Material-Y.

Referring again to FIG. 4, the active layer material is chosen to optimized the characteristics of the nanostructure to be formed in it. Thus, the material can be silicon or strained silicon, Ge III-V, II-VI semiconductors or any other material that is suitable for the desired nanostructure. The thickness of the active layer will not be required to be thicker than that required by the nanostructure being made and will thus be in a range from a fraction of a micrometer to several micrometers.

The bottom substrate layer is made from a material that will generally be silicon or other material that would be compatible with a standard silicon semiconductor processing environment. Thus, its thickness, shape and size would match that of a standard wafer. The material will be sacrificial since is will all be removed after Material-Y is processed to form nanostructures and bonded to its handle or 3-dimensional stack. Therefore, the bottom substrate material will generally be formed using the most economical, easily ground and etched material available.

The boundary layer would generally be made of a material that isolates the active layer from the bottom substrate material. The primary reason for the isolation is so that a portion of the bottom substrate can be selectively etched and the etch stopped within the boundary layer and not extend into active layer. Also, the boundary layer should isolate the active layer from the bottom substrate. The boundary layer preferably be made of an insulating material such as SiO₂, silicon nitride or alumina. SiO₂ appears to be the preferable material because it can serve as an etch stop in silicon etchants such as SF₆ or XeF₂, with selectivity as high as 100 to 150. Then, the SiO₂ layer would preferably be formed with a thickness in the range of 300 nm to 700 nm, although the thickness should not be restricted to these values.

The 3-dimensional stack is formed from Material-Y by using standard nanostructure processing techniques used in the formation of integrated circuit structures such as CMOS, linear, RF, MEMS, Ferroelectric and other nanostructures. A handle could also be used to attach stack elements. Furthermore, the handle could take the form of an integrated circuit structure such as a microprocessor for example. The top surface of the processed material is then planarized and suitably prepared to bond to the handle or 3-dimensional stack using processes in the prior art of the semiconductor and bonding industry. This structure is then bonded to the handle or 3-dimensional stack using a suitable bonding technique as is known in the prior art. A preferred method would be to use what is known as plasma activated or other low temperature bonding. This is described in the prior art. Vertical interconnection are made between layers that are either preformed in the active layer or are formed after the active layer is processed, bonded and thinned. Prior to thinning the bonded structure may be coated with a suitable protective layer such as silicon nitride or other such materials. The thinning process is generally accomplished by a combination of grinding and etching. Preferably, the grinding portion of the thinning will remove all but approximately 25 μm to 50 μm of the bottom substrate, but is not limited to this range. The final etch will be a selective etch that stops on or within the boundary layer. For an SiO₂ boundary layer with a silicon bottom substrate material dry etchants such as SF₆ or XeF₂ would be most suitable, or wet etchants such as KOH or EDP would be acceptable. The dry etchant SF₆ would be preferred with KOH another reasonable choice. Any final work on formation of the vertical interconnections is then accomplished, if necessary.

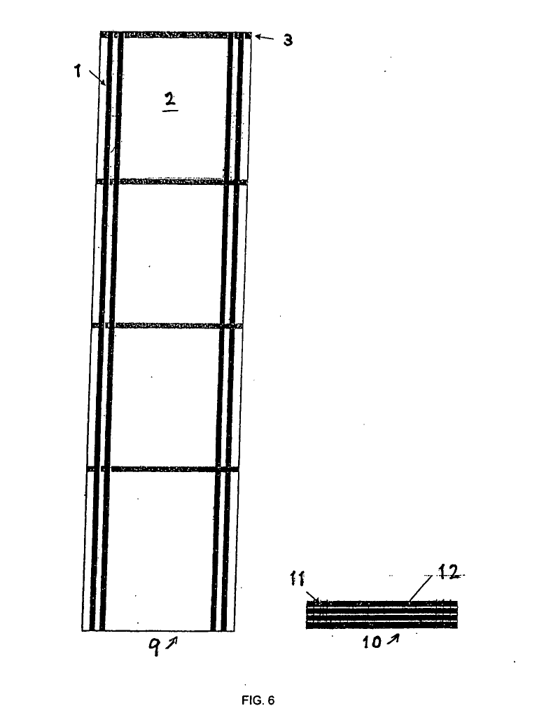

The 3-dimensional nanostructure stack may comprise any combination of the nanolayers described earlier and may also include interspersed layers to provide heat removal, RF isolation and other ancillary functions that may be needed in the engineering of the 3-dimensional nanostructure stack. Note that the three dimensional stack structures that are formed with either Material-X or Material-Y are quite distinct from conventional prior art grind and etch stacks. Both the Material-X and Material-Y 3-dimensional stacks will be in the range in thickness previously described in this specification which is thinner than stacks made using conventional prior art grind and etch methods and will have vertical interconnects that are much shorter than those in conventional prior art grind and etch stacks. These facts are illustrated in FIG. 6 which compares a conventional and intermediate boundary layer 3-dimensional nanostructure stacks that would result from the either such stacks formed using the methods and structures described in U.S. Published Patent Application No. 2004-0229443 A1 with regard to Material-X or in the foregoing description with regard to Material-Y.

### EXAMPLE

By way of example, and not of limitation, Material-Y can be used to make 3-d structures as follows:

1. Material-Y is made in wafer form to a thickness and size and other characteristics to match that used in the customer's integrated circuit (IC) or other fabrication line.

2. Material-Y is processed by the manufacturer to produce the customer's desired nanostructure.

3. Material-Y is then aligned bonded to a 3-d stack or other desired structure.

4. The substrate of Material-Y is then thinned back leaving only part or all of the intermediate insulator layer and nanostructure processed attached to the 3-d stack or other desired structure.

5. The intermediate insulator layer would then be selectively etched as desired leaving only the thin nanostructure processed layer attached to the 3-d stack or other structure.

6. Required via feed-through conductors would then be made to electrically connect this added layer to the entire structure. Since this layer of processed nanostructure may be ˜1 μm in thickness these interconnecting electrical vias are easily formed in a manner well known in the semiconductor industry.

7. Alternatively, the required via feed-through conductors could of course be made as part of the nanolayer before the bonding and grind and etch steps.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art. In the appended claims, reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

1. A material for use in fabricating a nanodevice, comprising:
an active layer;
a substrate layer; and
a boundary layer intermediate said active layer and said substrate layer.

2. A material as recited in claim 1:
wherein said active layer has a top surface having a contour; and
wherein said boundary layer has a contour that matches the contour of said top surface of said active layer.

3-5. (canceled)

6. A material as recited in claim 1, wherein said boundary layer comprises SiO2.

7. A material as recited in claim 1, wherein said boundary layer isolates said active layer from said substrate layer.

8-9. (canceled)

10. A material as recited in claim 1, wherein said active layer comprises a material optimized to characteristics of a device structure to be formed in said active layer.

11. A material as recited in claim 1, wherein said active layer comprises a material selected from the group of materials consisting essentially of silicon or strained silicon, Ge III-V, II-VI semiconductors or any other material that is suitable for the desired material.

12. A material as recited in claim 1, wherein said active layer has a thickness selected to facilitate fabrication of a device structure in said active layer.

13. A material as recited in claim 1, wherein said active layer has a thickness ranging from a fraction of a micrometer to several micrometers.

14. A material as recited in claim 1:
wherein said substrate layer comprises a sacrificial layer;
wherein said boundary layer comprises a sacrificial layer; and
wherein removal of said substrate layer and said boundary layer produces an active layer having a thickness equivalent to thickness of a device formed in said active layer.

15. (canceled)

16. A material as recited in claim 1, wherein said substrate layer has a thickness, shape and size of a standard wafer.

17. A material as recited in claim 1, wherein said substrate layer comprises a sacrificial layer.

18. A method of fabricating a nanodevice, comprising:
forming a material comprising an active layer, a substrate layer, and a boundary layer intermediate said active layer and said substrate layer;
processing said active layer with a device;
planarizing said active layer;
bonding said active layer to a handle or 3-dimensional stack;
thinning a portion of said substrate layer using a combination of grinding and etching;
thinning the remainder of said substrate layer with an etch that stops at or within the boundary layer; and
thinning said boundary layer to a locating at or near said active layer.

19. A method as recited in claim 18, further comprising:
forming required via feed-through conductors to electrically connect the processed active layer to another structure.

20. (canceled)

21. A method as recited in claim 18, further comprising coating said material with a protective layer prior to thinning.

22. (canceled)

23. A method as recited in claim 18, wherein said grinding of said substrate removes all but 25 μm to 50 μm of the substrate.

24. (canceled)

25. A method as recited in claim 18:
wherein said boundary layer comprises SiO₂; and
wherein said boundary layer is etched with an etchant selected from the group consisting essentially of SF₆, XeF2, KOH, and EDP

26. A multilayered material for fabrication of a nanodevice, comprising:
(a) a device layer;
(b) an insulator layer adjacent to said device layer; and
(c) a substrate layer adjacent to the insulator layer;
(d) wherein the device layer has a thickness and other characteristics optimized for processing of a desired nanostructure on the device layer;
(e) wherein the insulator layer has electrical insulation characteristics and etch resistance from the substrate layer such that, after subsequent processing, the substrate may be removed by polishing and etching to leave a nanostructure processed device layer as a thin layer bonded to a 3-d stack or other structure as a thin layer;
(f) wherein the substrate layer has been optimized to have a very high etch rate and to have a large difference between its etch rate and the etch rate of the insulator layer so that it can be selectively etched.

27-34. (canceled)
